(19) United States
(12) Patent Application Publication
(10) Pub. No.: US 2026/0008557 A1
(43) Pub. Date: Jan. 8, 2026

(54) SYSTEM AND METHOD FOR BALANCING BATTERY SYSTEMS BY ELECTRIC PROPULSION UNIT COMMANDS

(71) Applicant: Textron eAviation Inc., Wichita, KS (US)

(72) Inventors: Steven G. HAGEROTT, Wichita, KS (US); Rodd William FULLER, Valley Center, KS (US); Logan Daniel BRYANT, Wichita, KS (US)

(21) Appl. No.: 18/764,459

(22) Filed: Jul. 5, 2024

(51) Int. Cl. B64D 31/16; B60L 58/18; B64D 27/357; G01R 31/396; H01M 10/42; H01M 10/48

(52) U.S. Cl. CPC B64D 31/16; B60L 58/18; G01R 31/396; H01M 10/425; H01M 10/482; B60L 2200/10; B64D 27/357; B64D 2221/00; H01M 2010/4271; H01M 2220/20

(57) ABSTRACT

The technology described herein relates to, among other topics, an aircraft flight system (or any vehicle system) for balancing loads across different distributed power units (e.g., batteries). In particular, the technology is directed to balancing battery systems (e.g., in aircraft with multiple isolated battery systems used for electric propulsion) using electric propulsion unit commands.

### BACKGROUND

The ability to fly is something that has captivated human civilization for centuries. Aircraft give us the freedom to easily navigate around the globe in a fraction of the time compared to other methods of transportation. Many aircraft operate using conventional propulsion systems that utilize standard aircraft fuel. However, certain aircraft exist that are primarily (or substantially) electrically powered (e.g., using one or more batteries). Such battery powered aircraft can conventionally operate without “burning” fuel thereby providing a “cleaner” flight for the environment.

These electric aircraft can have multiple isolated battery systems that are used for propulsion of the aircraft. These battery systems can be connected to the electrical loads in the aircraft, including motors, in a distributed fashion where only certain loads are connected to certain battery systems. If, during flight the electrical load is not distributed evenly across the battery systems, then one battery system will drain faster than the others. This drain will reduce the effective range of the aircraft since some of the battery systems will be reduced to a “low” state of charge prompting the end of the flight. The unused charge in the remaining battery systems will not be able to be used to extend the flight time. It should be appreciated that the loads across the battery systems must be evenly distributed in order to get the most amount of range out of the aircraft.

Accordingly, it will be appreciated that new and improved techniques, systems, and processes are continually sought after.

### BRIEF DESCRIPTION OF THE DRAWINGS

The foregoing and other objects, features and/or advantages will be apparent from the following description of particular embodiments, as illustrated in the accompanying drawings in which like reference characters refer to the same parts throughout the different views. The drawings are not necessarily to scale, emphasis instead being placed upon illustrating the principles of various example embodiments. Each embodiment herein may be used in combination with any other embodiment(s) described herein.

FIG. 1 shows a non-limiting example aircraft 100;

FIG. 2 shows a non-limiting example block diagram of certain components of a system 1 used to operate aircraft 100;

FIG. 3 shows a further non-limiting example block diagram of system 1;

FIG. 4 shows a non-limiting example flowchart of various processes carried out in association with system 1;

FIG. 5 shows a non-limiting example flowchart for processes associated with system 1;

FIGS. 6A-D show non-limiting example diagrams of different example arrangements where power levels are measured and adjusted; and

FIG. 7 shows a non-limiting example block diagram of a hardware architecture.

### DETAILED DESCRIPTION OF EXAMPLE EMBODIMENTS

### Overview

The technology described herein relates to, among other topics, an aircraft flight system for balancing loads across different distributed power units (e.g., batteries). In particular, the technology is directed to balancing battery systems (e.g., in aircraft with multiple isolated battery systems used for electric propulsion) using electric propulsion unit commands.

An electric aircraft may have a plurality of batteries coupled to one or more rotors. Each rotor on the electric aircraft can be powered by dual electric motors or a dual winding motor. Each electric motor (or each set of windings) can be tied to a unique (e.g., separate) battery system.

The technology described herein includes a flight control system that can command more power from one electric motor (set of windings) or less from the other. This approach would allow the total rotor power to be at the desired level, while also balancing the electrical loading on each battery system. The advantage of this approach is that it does not require any additional hardware to be added to the aircraft for the specific purpose of balancing battery state of charge across the isolated battery systems. In one example embodiment, these features can be implemented using various software executed by computing equipment of the aircraft. Certain example alternative embodiments include directly tying the batteries together and/or adjusting other loads connected to the battery systems.

It should be appreciated that the technology described in this application includes specific examples associated with aircraft technology. However, this example is non-limiting and the technology described herein can be used in any application for any moving vehicle (or any system employing one or more batteries). For example, the techniques described herein can also be applied to ground-based vehicles (e.g., automobiles) as well as water-based or space-based vehicles.

In many places in this document, software modules and actions performed by software modules may be described. This is done for ease of description; it should be understood that, whenever it is described in this document that a software module performs any action, the action is in actuality performed by underlying hardware components (such as a processor and a memory) according to the instructions and data that comprise the software module.

It should also be appreciated that some of the components described in the figures (and throughout any other portion of this document) may be referred to as singular or plural components. However, these descriptions are for illustration purposes and are non-limiting. For example, if a component is referred to as a system, it should be understood that the system could comprise a single component, or could be multiple components (included distributed components). Likewise, if a component is referred to as a plurality, it should be appreciated that the component may also be implemented via a single component as well.

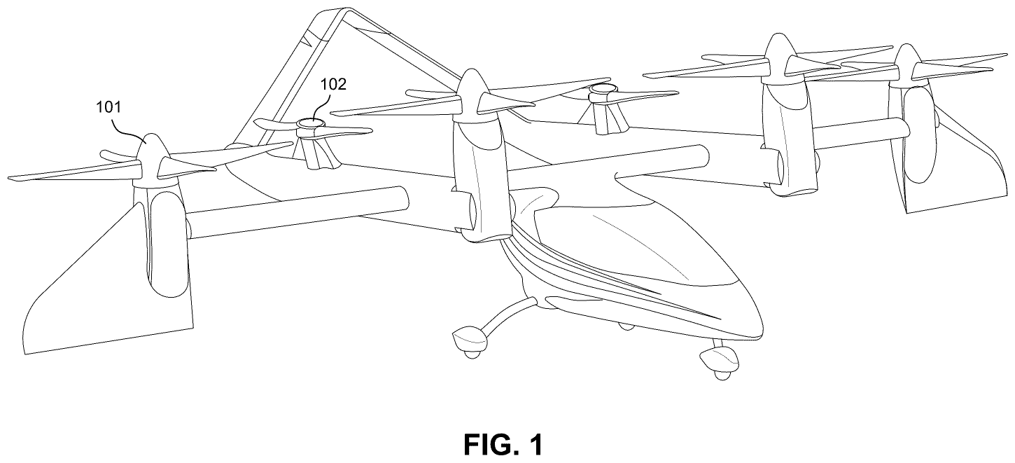

FIG. 1 shows a non-limiting example aircraft 100 where certain aspects of the technology described herein may be implemented. In one example embodiment, aircraft 100 may include an electric aircraft having one or more battery systems used to operate different motor assemblies. Aircraft 100 can include front propulsion units 101 (e.g., front propellers) as well as back propulsion units 102 (e.g., back propellers).

Each propulsion unit 101/102 may be operated by one or more motors. Each motor may be coupled to one or more battery systems where the propulsion units 101/102 are powered. It should be appreciated that propulsion units 101/102 are depicted as propellors in FIG. 1. But, this example is non-limiting and the technology described herein envisions any type of propulsion unit 101/102 for operating an aircraft.

Moreover, the propulsion units 101/102 are shown in a specific configuration in FIG. 1 (e.g., extending vertically from a horizontal plane of the aircraft). But, this example is non-limiting and propulsion units 101/102 can be operated in other configurations. For example, front propulsion units 101 may be operated so that they are aligned along a horizontal plane of the aircraft (e.g., forward-facing as opposed to upward-facing).

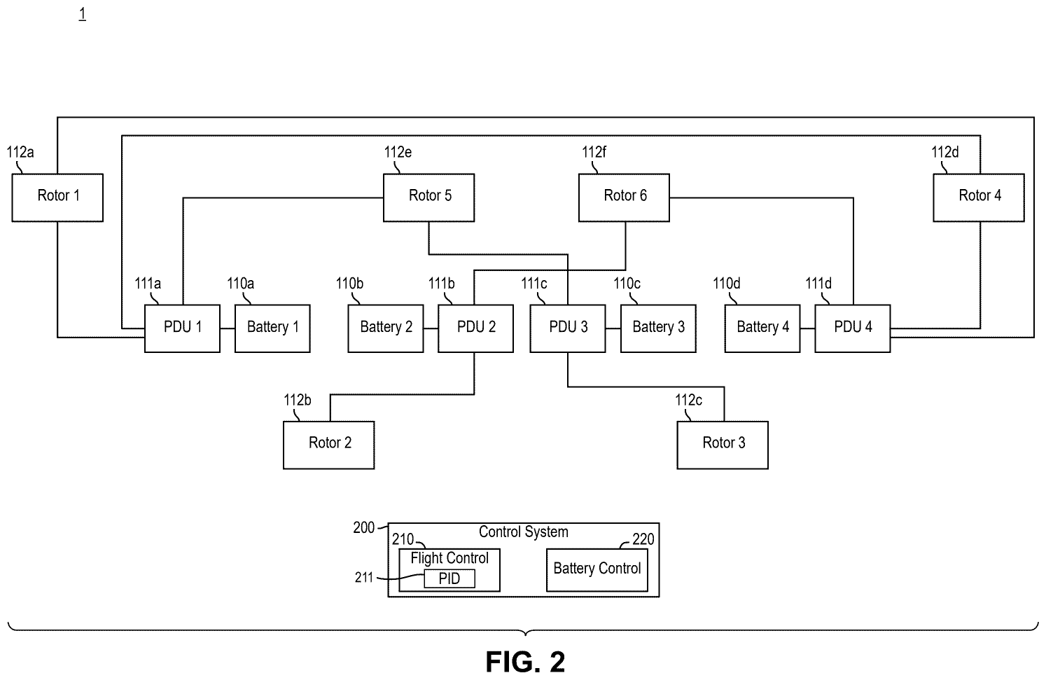

FIG. 2 shows a non-limiting example block diagram of certain components of a system 1 used to operate aircraft 100. In one example embodiment, system 1 may include batteries 110a-110d where each of batteries 110a-110d may be operatively coupled to power distribution units (PDU) 111a-d. The example shown in FIG. 2 depicts four batteries and four associated PDUs. However, these examples are non-limiting and the technology described herein can include any number of batteries or PDUs.

Each PDU 111a-d may be operatively coupled to one or more rotors 112a-f. It should be appreciated that the example shown in FIG. 2 depicts each rotor 112a-f being coupled to at least two PDUs (of PDU 111a-d). However, this example is of course non-limiting and rotors 112a-f can be coupled to any number of PDUs. Moreover, each rotor may be coupled to a different number of PDUs. For example, one rotor may be coupled to two PDUs where another rotor may be coupled to one or even three PDUs.

In the example of FIG. 2, rotors 112a and 112d-f may constitute a rotor assembly at the “front” of the aircraft where rotors 112b and 112c may constitute a rotor assembly at the “back” of the aircraft. As a non-limiting example, PDU 111a may be coupled to “front” rotors 112a, 112d, and 112e, while PDU 111b may be coupled to “front” rotor 112f and “back” rotor 112b. Likewise, PDU 111d may be coupled to “front” rotors 112a, 112d, and 112f, while PDU 111c may be coupled to “front” rotor 112e and “back” rotor 112c.

System 1 may also include one or more control system(s) 200 used in association with operating aircraft 100. In one example embodiment, control system(s) 200 may include various components for operating various elements associated with system 1. As a non-limiting example, control system(s) 200 may include flight control 210 and/or battery control 220.

It should be appreciated that battery control 220 may include one or more components for detecting energy levels associated with each of batteries 110a-110d. For example, battery control 220 may detect different state-of-charge of each of batteries 110a-d where such information may be reported to control system 200. These examples are of course non-limiting and battery control 220 could perform any variety of tasks.

Flight control 210 may include one or more components for controlling operation of aircraft 100. In one example embodiment, flight control 210 may include various circuitry (e.g., processor, memory, input/output interface) used in association with flying aircraft 100. Such circuitry could be responsible for directly or indirectly operating aircraft 100. Likewise, the various circuitry of flight control 210 may be used in carrying out various processes and methods described herein. For example, flight control 210 may be used to manage power levels associated with different electronic propulsion units used in system 1. Flight control 210 may include a proportional-integral-derivative (PID) controller 211 used to adjust torque commands for individual motors. These examples are of course non-limiting and flight control 210 can be used to perform any variety of tasks associated with system 1.

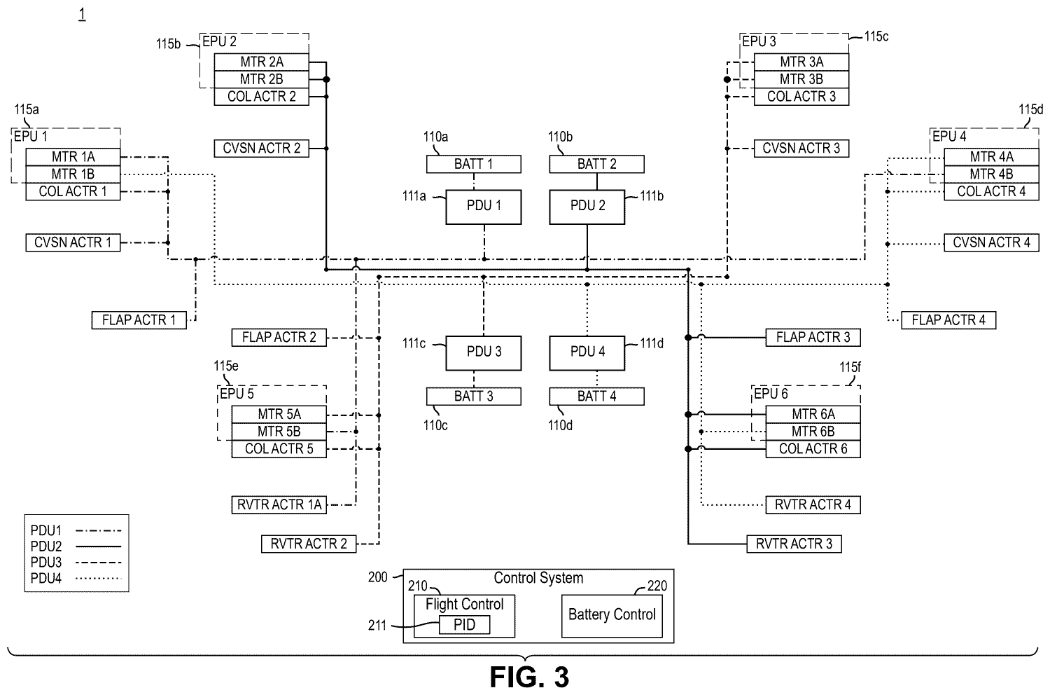

FIG. 3 shows a further non-limiting example block diagram of system 1. In the example shown in FIG. 3, various further details are shown with respect to the components of system 1, as shown in FIG. 2. In particular, system 1 (as shown in FIG. 3) includes the batteries 110a-d which are respectively coupled to the PDUs 111a-d.

System 1 further shows electric propulsion unit(s) (EPU) 115a-f which are coupled to PDUs 111a-d. EPUs 115a-f may each include a plurality of motors where EPUs 115a-f operate each motor. For example, EPU 115a operates dual electric motors (or a dual winding motor) MTR 1A/1B (where EPUs 115b-f are similarly configured). Each EPU 115a-f (and respective motor assembly) may also include additional components to which they are associated (and to which PDUs 111a-d are coupled). For example, each EPU 115a-f may be operatively coupled to a collective actuator (COL ACTR), conversion actuator (CVSN ACTR), flaperon actuator (FLAP ACTR), and/or ruddervator actuator (RVTR ACTR).

Similar to the arrangement shown in FIG. 2, EPUs 115a-f may have different coupling arrangements to PDUs 111a-d. In particular, PDUs 111a-d may be coupled to different components associated with EPUs 115a-f. For example, each PDU 111a-d may be coupled to one motor (of the dual electric motor) of EPUs 115a-f, while another PDU may be coupled to the other motor (as well as the other components) of EPUs 115a-f.

In the example shown in FIG. 3, PDU 111a is operatively coupled to MTR 1A (along with the other components associated with EPU 115a) while also coupled to MTR 5B (along with RVTR ACTR 1A associated with EPU 115e) and MTR 4B (associated with EPU 115d). Likewise, PDU 111d is operatively coupled to MTR 4A (along with the other components associated with EPU 115d) while also coupled to MTR 6B (along with RVTR ACTR 4 associated with EPU 115f) and MTR 1B (associated with EPU 115a).

PDU 111b is operatively coupled to MTR 6A (along with the other components associated with EPU 115f) while also coupled to MTR 2A/2B (and all other components associated with EPU 115b). Likewise, PDU 111c is operatively coupled to MTR 5A (along with the other components associated with EPU 115e) while also coupled to MTR 3A/3B (and all other components associated with EPU 115c).

It should be appreciated that EPUs 115a-d constitute a “front” assembly of aircraft 100 while EPUs 115e and 115f constitute a “rear” assembly of aircraft 100. Thus, and as a non-limiting example, the operatively coupling of the various PDUs 111a-d are arranged in a manner to properly provide power to each of the “front” and “rear” assemblies configured by EPUs 115a-f. These examples are of course non-limiting and the technology described herein envisions any type of coupling arrangement between the various components shown in FIG. 3.

As noted above, system 1 further includes control system(s) 200 which could include, at least, flight control 210 and/or battery control 220. One or more components of control system(s) 200 could be directly (or indirectly) connected to each of the components shown in FIG. 3, as a non-limiting example. For example, PID controller 211 could be connected to each of EPU 115a-f. Likewise, PID controller 211 could also be connected to any of the actuators (e.g., FLAP ACTR, CVSN ACTR) shown in FIG. 3. These examples are of course non-limiting and any component of control system(s) 200 could be operatively coupled to various components shown in FIG. 2 or 3.

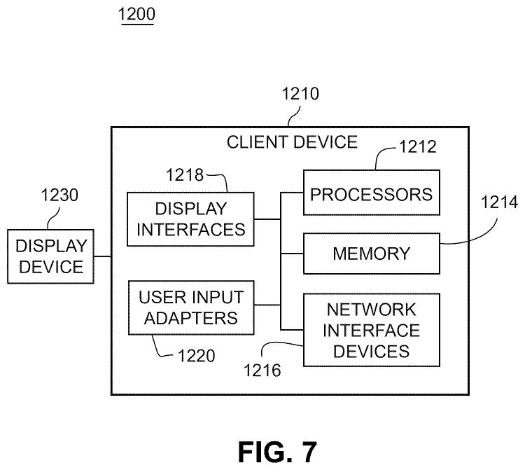

It should also be appreciated that various elements of control system(s) 200 could be implemented using different hardware circuitry shown, as a non-limiting example, with respect to FIG. 7. This example is of course non-limiting, and the components of control system(s) 200 could be implemented using hardware, software, or any combination of hardware and software. It should be further appreciated that system 1 may include multiple control system(s) 200, or may include a single control system(s) 200 with multiple components (e.g., flight control 210, battery control 220) within control system(s) 200. Such an approach would allow system 1 to include redundant systems in the event one system fails (e.g., during operation of aircraft 100).

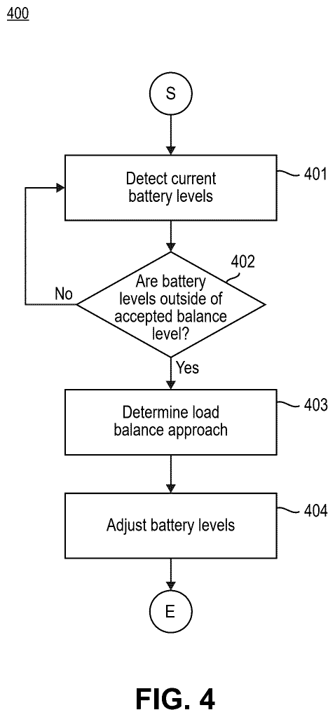

FIG. 4 shows a non-limiting example flowchart of various processes carried out in association with system 1. In one non-limiting example embodiment, the processes shown in the flowchart of FIG. 4 depict different actions carried out in association with managing power levels across different battery systems. In one example embodiment, the processes shown in FIG. 4 may be implemented via different software programs (e.g., executing one or more instructions associated with electronic propulsion unit commands). It should be appreciated that any software programs may be executed in association with the hardware components shown, for example, in FIG. 7.

The process begins (at action 401) by detecting current energy levels (e.g., state-of-charge levels) of one or more batteries (e.g., batteries 110a-d). The system 1 can obtain certain information associated with the energy levels of different batteries 110a-d where a value (e.g., numerical value) can be provided to indicate the energy level. System 1 may typically obtain the energy levels during operation (e.g., in-flight) but this example is non-limiting and system 1 can obtain the energy levels of batteries 110a-d at any time.

Upon obtaining the energy levels of batteries 110a-d, system 1 may (at action 402) determine whether one or more energy levels of batteries 110a-d satisfy certain criteria. For example, system 1 may determine whether one or more of batteries 110a-d are outside of an accepted energy balance (or load) level. If the batteries 110a-d do not satisfy the certain criteria, the process may repeat (at action 401) where system 1 continually monitors batteries 110a-d to check the various energy levels. Alternatively, system 1 may end the process associated with monitoring the various energy levels of batteries 110a-d.

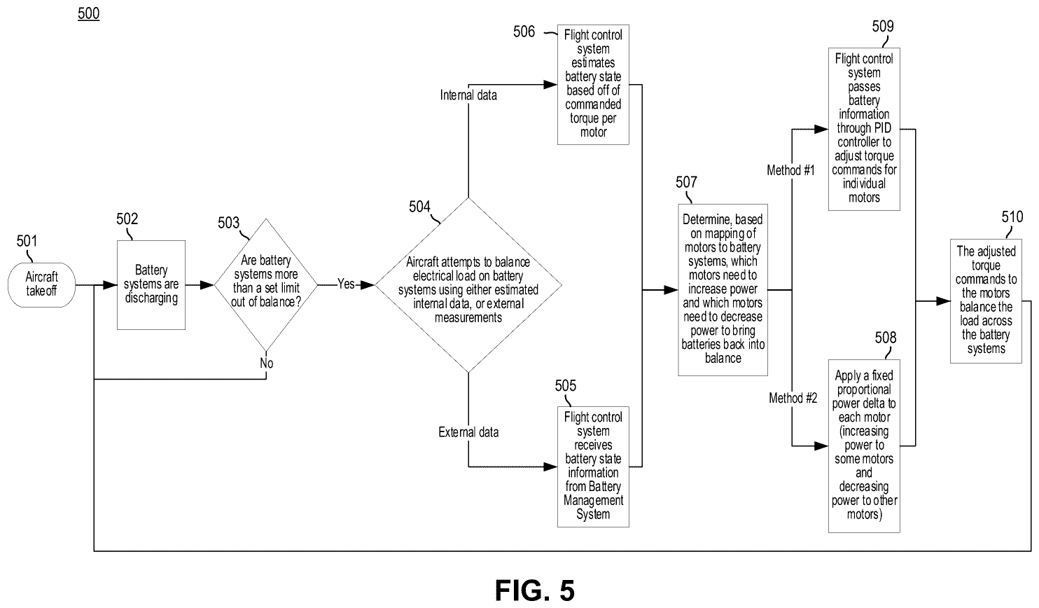

If one or more energy levels of batteries 110a-d satisfy the criteria (e.g., the energy levels are outside of an accepted balance level), system 1 may (at action 403) determine a load balance approach (e.g., from one or more load balance approaches). In one example embodiment, system 1 may determine a load balance approach using various types of data that could include internal and/or external data. Moreover, system 1 may determine a load balance approach based on different mappings associated with the batteries 110a-d and other components (e.g., motors). Such further information regarding these approaches are presented in more detail with respect to FIG. 5, discussed herein.

After determining an appropriate load balance approach, system 1 may (at action 404) adjust one or more energy levels associated with batteries 110a-d. In particular, system 1 may adjust the energy levels of batteries 110a-d so that the energy level values are equal across all of batteries 110a-d. Alternatively, system 1 may adjust energy level values of batteries 110a-d unequally (e.g., in a manner and level appropriate for each battery).

Although actions 401-404 are shown in FIG. 4 as occurring once, these actions 401-404 may, in various embodiments, be repeated a number of times. Moreover, actions 401-404 can be combined together (e.g., as a single process) or divided into further sub-processes. Likewise, although actions 401-404 are shown in a specific order, it should be appreciated that in certain example embodiments, the steps in any action can be carried out in any order at any number of times.

FIG. 5 shows a non-limiting example flowchart for processes associated with system 1. In particular, FIG. 5 shows a process 500 for adjusting loads among different power and/or battery systems. The process begins (at action 501) where the battery system begins operation (e.g., as the aircraft or vehicle is being used). For example, in the case of an aircraft, the process begins when the aircraft has taken off and the battery system is in full operation. Alternatively, the process can also begin when the system is powered on, but has not taken off (e.g., the system is operation while the vehicle is idling on the ground).

As the battery system is operation (e.g., as the aircraft is flying), the process (at action 502) continues where one or more battery systems begin discharging. For example, each respective motor arrangement can require different batteries to discharge in accordance with the electrical needs of the motor arrangement. After the battery systems begin discharging, the system 1 may (at action 503) determine if one or more battery systems exceed a set limit for being “out of balance.” For example, the system 1 may determine if one or more battery systems are outside of a percentage threshold balance level (e.g., 5%). As another example, system 1 may determine if one or more battery systems drop below a detected state-of-charge level.

If the battery systems are not more than a set limit “out of balance,” system 1 may continue operation without making any immediate adjustments to load levels. If the battery systems are detected as being more than a set limit “out of balance,” the process proceeds (at action 504) for system 1 to attempt to balance electrical load(s) on different battery systems. In one non-limiting example embodiment, system 1 may attempt to balance electrical load(s) on different battery systems using internal data (or measurements) and/or external data (or measurements).

In one example embodiment, system 1 may (at action 506) use internal data to adjust various motor commands to balance loads on different battery systems. For example, system 1 may (e.g., using a flight control system) estimate battery states based off commanded torque per motor. That is, system 1 may use expected battery drain (e.g., using internal data) to determine battery levels among each battery system, and then use such data to adjust the battery levels (e.g., to an equal or near equal level).

As another non-limiting example, system 1 may (at action 505) receive (e.g., via a flight control system) battery state information from a battery management system. In one example embodiment, system 1 may understand a battery state of charge level (e.g., as a percentage value) rather than determining (or estimating) different battery energy levels. For example, system 1 may determine different state of charge percentages for each battery and then adjust the battery level of each battery system based on the associated percentage.

Upon determining the different battery energy levels (and/or battery state of charge values), system 1 may (at action 507) determine which motor arrangements require power modification. In particular, system 1 may determine which motor arrangements require power levels to be increased, and/or system 1 may determine which motor arrangements require power levels to be decreased. In one example embodiment, system 1 may determine which motor arrangements require power adjustment based on a mapping of motors to battery systems (e.g., as shown in FIGS. 2 and 3).

It should be appreciated that system 1 may use any variety of methods for determining which motor arrangements require power modification. For example, system 1 may (at action 509) pass battery information (e.g., using a flight control system) through a proportional-integral-derivative (PID) controller 211 to adjust torque commands for individual motors. In one example embodiment, system 1 may provide the PID controller 211 with the battery levels (and/or instructions regarding battery levels) where PID controller 211 can adjust torque on each individual motor thereby reducing or increasing power consumption for the respective motor.

As another non-limiting example, system 1 may (at action 508) apply a fixed value to each motor for adjusting power levels of the motor. For example, system 1 may, based on mapping(s) of motors to battery systems, apply a fixed proportional “delta” value to each motor thereby increasing power to some motors and/or decreasing power to other motors. In one example embodiment, system 1 may apply a “delta” adjustment value to each motor whereby the motor power value will be increased or decreased based on the “delta” value. These examples are of course non-limiting and the technology described herein envisions any variety of methods for adjusting power levels of different motors.

Upon determining an appropriate method, system 1 may (at action 510) perform adjustment of power levels of different motors. For example, system 1 may adjust torque commands to the different motors to balance the load across the battery systems. In doing so, system 1 advantageously operates the vehicle in manner that provides efficient use of the battery system (thereby improving overall operation of the vehicle). For example, by carrying out the process 500, system 1 can enable an aircraft to fly longer and/or farther via more efficient use of the battery system.

Although actions 501-510 are shown in FIG. 5 as occurring once, these actions 501-510 may, in various embodiments, be repeated a number of times. Moreover, actions 501-510 can be combined together (e.g., as a single process) or divided into further sub-processes. Likewise, although actions 501-510 are shown in a specific order, it should be appreciated that in certain example embodiments, the steps in any action can be carried out in any order at any number of times.

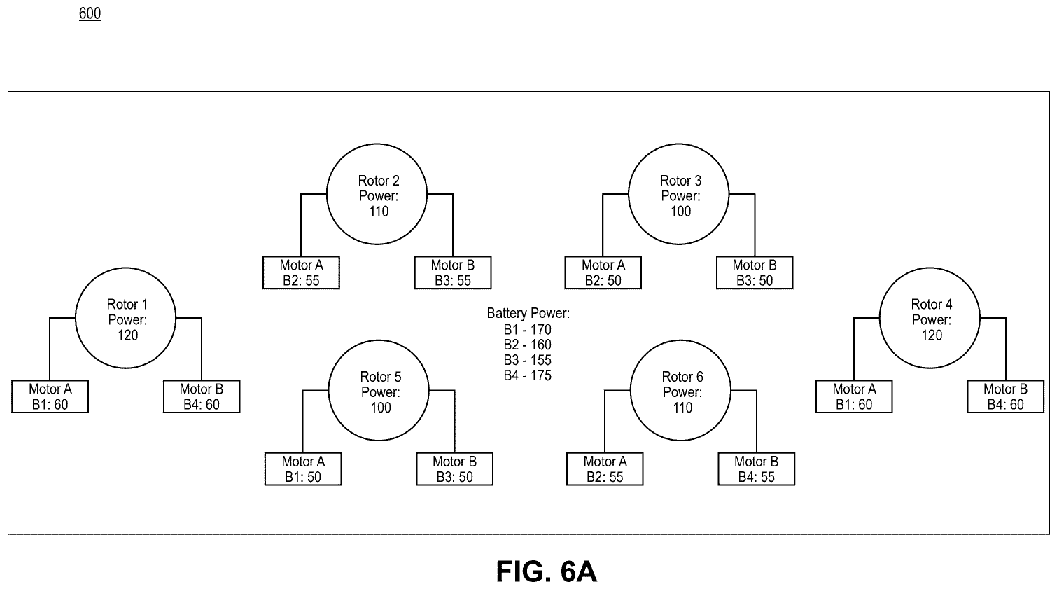

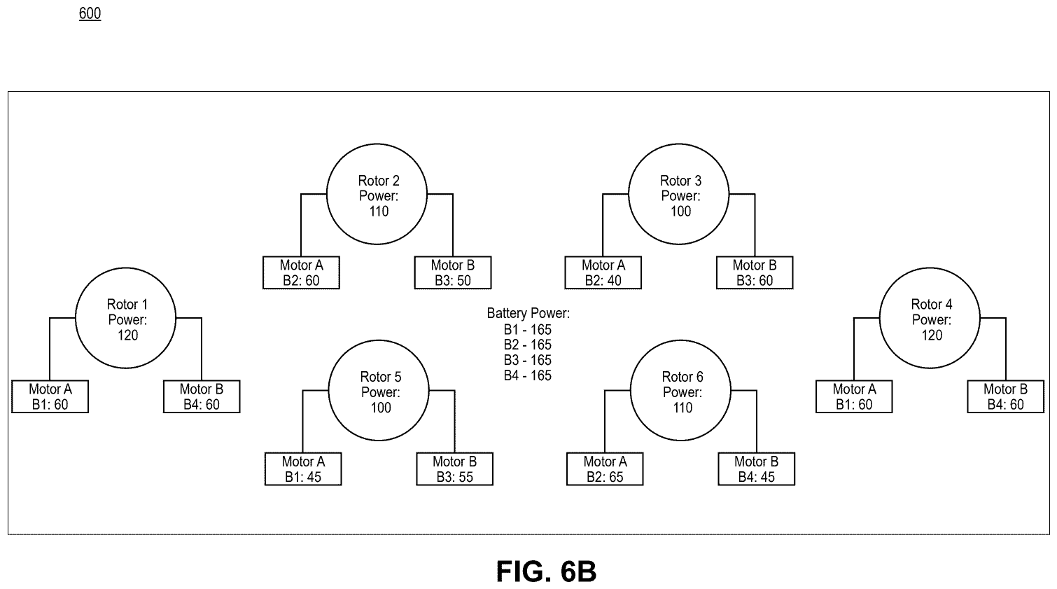

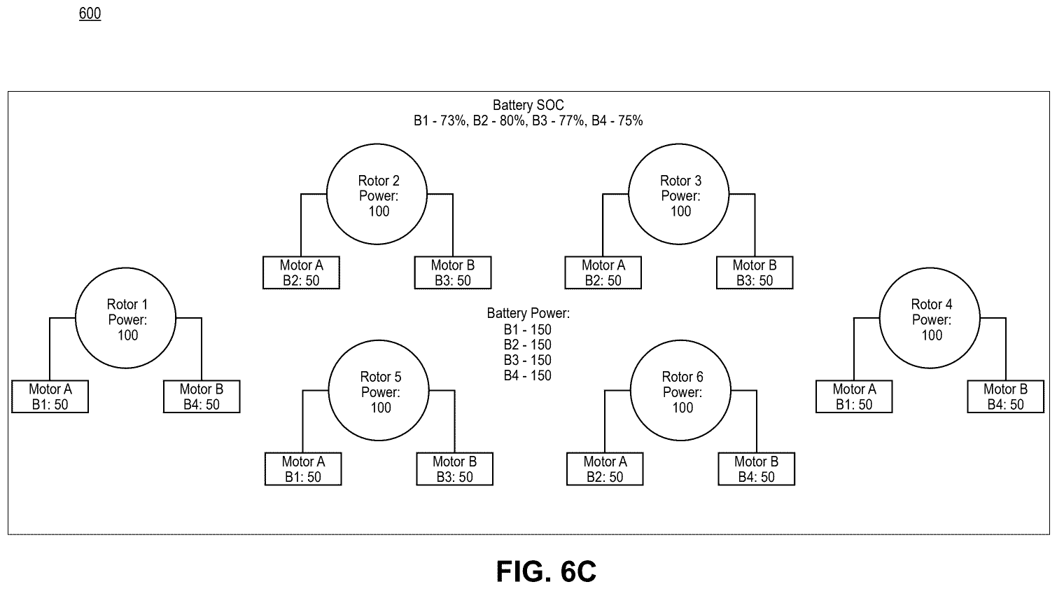

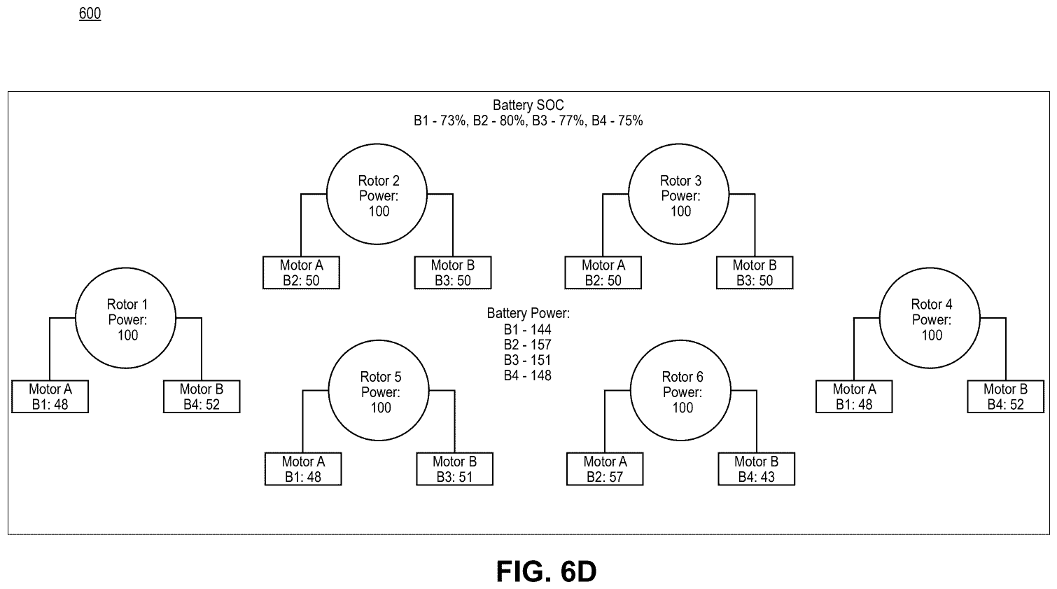

FIGS. 6A-D show non-limiting example diagrams of different example arrangements where levels are measured and adjusted across different power systems. In particular, FIGS. 6A-D shows arrangements 600 depicting different motors and/or rotors where power values are determined and then modified.

In the examples shown in FIGS. 6A and 6B, example arrangements 600 are shown where system 1 determines battery energy levels and then makes various adjustments. FIG. 6A specifically shows a non-limiting example arrangement 600 where no adjustment has been performed, while FIG. 6B shows a non-limiting example arrangement 600 where commands for adjustment are issued. In the examples of FIGS. 6A and 6B, system 1 can use expected battery drain and knowledge of mapping between electric propulsion motor channels and batteries to adjust motor commands to balance loads on the battery systems.

FIG. 6A specifically shows six different rotors having individual dual-motor arrangements at each rotor. In the example of FIG. 6A, four battery systems (labeled B1-B4) are connected to certain motor arrangements (of the dual-motor arrangement) where each battery system is delivering an associated power level. For example, battery B1 is delivering a power level of 170, battery B2 is delivering a power level of 160, battery B3 is delivering a power level of 155, and battery B4 is delivering a power level of 175. Each motor connected to each battery system B1-B4 has an operating power level that, when totaled among the respective motors, should equal the total power level of each battery system B1-B4. For example, battery B1 is connected to rotor 1/motor A, rotor 5/motor A, and rotor 4/motor A having respective power levels of 60, 50, and 60 (totaling to 170 matching the power level of battery system B1). Battery systems B2-B4 share similar arrangements as shown in FIG. 6A.

After adjusting the power levels (e.g., using the expected battery drain and knowledge of mapping between electric propulsion motor channels and batteries), system 1 can modify battery systems B1-B4 power levels. In the example shown in FIG. 6B, battery systems B1-B4 adjust levels from 170, 160, 155, and 175, respectively, to 165 for each of battery systems B1-B4. In the specific example shown in FIG. 6B, the power level of rotor 5/motor A is decreased from a value of 50 to 45 (which the power levels of rotor 1/motor A and rotor 4/motor A remain at a value of 60).

It should be appreciated that, in the example shown in FIG. 6B, the power level at each associated rotor arrangement remains the same (e.g., as shown in FIG. 6A) while the power levels for certain motors (of the dual motor arrangements) are modified. For example, rotor 5 remains at power level 100 (in both FIGS. 6A and 6B) while associated motor A is reduced to a level of 45 while motor B is increased to a level of 55 (thereby keeping a power level of 100 at rotor 5). System 1 can thus modify different levels at each rotor while keeping the general power level(s) of the rotor arrangement at similar level(s) (and at the same time adjusting the load on the respective battery system).

FIGS. 6C and 6D show further non-limiting example arrangements 600 where system 1 determines battery power levels and then makes various adjustments. FIG. 6C specifically shows a non-limiting example arrangement 600 where no adjustment has been performed, while FIG. 6D shows a non-limiting example arrangement 600 where commands for adjustment are issued. In the examples of FIGS. 6C and 6D, system 1 can use a battery state of charge and knowledge of mappings between electric propulsion motor channels and batteries to adjust motor commands to rebalance the battery state of charge.

In the example shown in FIG. 6C, each battery system B1-B4 has the same (or substantially same) level (e.g., 150). Each rotor arrangement and associated motor (e.g., of the dual motor arrangement) also operates at the same (or substantially same) level (e.g., each rotor has a power level of 100 while each motor pair each has a power level of 50).

FIG. 6C thus depicts a battery state of charge for each battery system B1-B4. For example, battery system B1 has a 73% state of charge, battery system B2 has an 80% state of charge, battery system B3 has a 77% state of charge, while battery system B4 has a 75% state of charge. System 1 may adjust (e.g., using the battery state of charge and knowledge of mappings between electric propulsion motor channels and batteries) the power levels of the different battery systems.

FIG. 6D shows adjustment of battery systems B1-B4 using the methods described in association with FIG. 6C. In the example shown in FIG. 6D, the battery systems B1-B4 are adjusted in association with their associated state of charge levels. That is, battery systems B1-B4 are increased or decreased relative to their proportionate state of charge with each other battery system.

As a non-limiting example, the average state of charge across battery systems B1-B4 (as shown in FIGS. 6C and 6D) is 76.25% where the battery systems B1-B4 power levels are adjusted in accordance with this average value. Thus, battery system B1 is reduced from 150 to 144 (e.g., 73/76.25*150), while battery system B2 is increased from 150 to 157 (e.g., 80/76.25*150). Likewise, battery system B3 is increased from 150 to 151 (e.g., 77/76.25*150), while battery system B4 is reduced from 150 to 148 (e.g., 75/76.25*150). It should be appreciated that this approach is of course non-limiting, and system 1 can use any method for making the adjustments shown with respect to FIGS. 6C and 6D (as well as FIGS. 6A and 6B). For example, system 1 may use predictive models in the software that adjusts the loads to meet at a point “in the future” (e.g., as opposed to reacting to the current state of charge). These examples are of course non-limiting and the technology described herein envisions any variety of methodology for adjusting loads within system 1.

In the example shown in FIG. 6D, the power level at each associated rotor remains the same (or substantially the same) having a value of approximately 100. The individual motor arrangements for each rotor, however, are adjusted in association with adjustments of the different battery systems B1-B4. For example, rotor 1/motor A is adjusted from 50 to 48, while rotor 1/motor B is adjusted from 50 to 52 (thus keeping the overall power level at rotor 1 at 100). These examples are of course non-limiting and the technology described herein envisions and variety of mechanisms for adjusting power levels across different battery systems.

FIG. 7 shows a non-limiting example block diagram of a hardware architecture for the system. As discussed herein, various components within system 1 may be implemented using the components of the hardware architecture shown in FIG. 7. For example, control system 200 may be comprised of one or more components shown with respect to FIG. 7.

In the example shown in FIG. 7, a client device 1210 (which may also be referred to as “client system” herein) includes one or more of the following: one or more processors 1212; one or more memory devices 1214; one or more network interface devices 1216; one or more display interfaces 1218; and one or more user input adapters 1220. Additionally, in some embodiments, the client device 1210 is connected to or includes a display device 1230. As will explained below, these elements (e.g., the processors 1212, memory devices 1214, network interface devices 1216, display interfaces 1218, user input adapters 1220, display device 1230) are hardware devices (for example, electronic circuits or combinations of circuits) that are configured to perform various different functions for the client device 1210.

In some embodiments, each or any of the processors 1212 is or includes, for example, a single- or multi-core processor, a microprocessor (e.g., which may be referred to as a central processing unit or CPU), a digital signal processor (DSP), a microprocessor in association with a DSP core, an Application Specific Integrated Circuit (ASIC), a Field Programmable Gate Array (FPGA) circuit, or a system-on-a-chip (e.g., an integrated circuit that includes a CPU and other hardware components such as memory, networking interfaces, and the like). And/or, in some embodiments, each or any of the processors 1212 uses an instruction set architecture such as x86 or Advanced RISC Machine (ARM).

In some embodiments, each or any of the memory devices 1214 is or includes a random access memory (RAM) (such as a Dynamic RAM (DRAM) or Static RAM (SRAM)), a flash memory (based on, e.g., NAND or NOR technology), a hard disk, a magneto-optical medium, an optical medium, cache memory, a register (e.g., that holds instructions), or other type of device that performs the volatile or non-volatile storage of data and/or instructions (e.g., software that is executed on or by processors 1212). Memory devices 1214 are examples of non-volatile computer-readable storage media.

In some embodiments, each or any of the network interface devices 1216 includes one or more circuits (such as a baseband processor and/or a wired or wireless transceiver), and implements layer one, layer two, and/or higher layers for one or more wired communications technologies (such as Ethernet (IEEE 802.3)) and/or wireless communications technologies (such as Bluetooth, WiFi (IEEE 802.11), GSM, CDMA2000, UMTS, LTE, LTE-Advanced (LTE-A), and/or other short-range, mid-range, and/or long-range wireless communications technologies). Transceivers may comprise circuitry for a transmitter and a receiver. The transmitter and receiver may share a common housing and may share some or all of the circuitry in the housing to perform transmission and reception. In some embodiments, the transmitter and receiver of a transceiver may not share any common circuitry and/or may be in the same or separate housings.

In some embodiments, each or any of the display interfaces 1218 is or includes one or more circuits that receive data from the processors 1212, generate (e.g., via a discrete GPU, an integrated GPU, a CPU executing graphical processing, or the like) corresponding image data based on the received data, and/or output (e.g., a High-Definition Multimedia Interface (HDMI), a DisplayPort Interface, a Video Graphics Array (VGA) interface, a Digital Video Interface (DVI), or the like), the generated image data to the display device 1230, which displays the image data. Alternatively or additionally, in some embodiments, each or any of the display interfaces 1218 is or includes, for example, a video card, video adapter, or graphics processing unit (GPU).

In some embodiments, each or any of the user input adapters 1220 is or includes one or more circuits that receive and process user input data from one or more user input devices (not shown) that are included in, attached to, or otherwise in communication with the client device 1210, and that output data based on the received input data to the processors 1212. Alternatively or additionally, in some embodiments each or any of the user input adapters 1220 is or includes, for example, a PS/2 interface, a USB interface, a touchscreen controller, or the like; and/or the user input adapters 1220 facilitates input from user input devices (not shown) such as, for example, a keyboard, mouse, trackpad, touchscreen, etc.

In some embodiments, the display device 1230 may be a Liquid Crystal Display (LCD) display, Light Emitting Diode (LED) display, or other type of display device. In embodiments where the display device 1230 is a component of the client device 1210 (e.g., the computing device and the display device are included in a unified housing), the display device 1230 may be a touchscreen display or non-touchscreen display. In embodiments where the display device 1230 is connected to the client device 1210 (e.g., is external to the client device 1210 and communicates with the client device 1210 via a wire and/or via wireless communication technology), the display device 1230 is, for example, an external monitor, projector, television, display screen, etc. . . .

In various embodiments, the client device 1210 includes one, or two, or three, four, or more of each or any of the above-mentioned elements (e.g., the processors 1212, memory devices 1214, network interface devices 1216, display interfaces 1218, and user input adapters 1220). Alternatively or additionally, in some embodiments, the client device 1210 includes one or more of: a processing system that includes the processors 1212; a memory or storage system that includes the memory devices 1214; and a network interface system that includes the network interface devices 1216.

The client device 1210 may be arranged, in various embodiments, in many different ways. As just one example, the client device 1210 may be arranged such that the processors 1212 include: a multi (or single)-core processor; a first network interface device (which implements, for example, WiFi, Bluetooth, NFC, etc. . . . ); a second network interface device that implements one or more cellular communication technologies (e.g., 3G, 4G LTE, CDMA, etc. . . . ); memory or storage devices (e.g., RAM, flash memory, or a hard disk). The processor, the first network interface device, the second network interface device, and the memory devices may be integrated as part of the same system-on-chip (e.g., one integrated circuit chip). As another example, the client device 1210 may be arranged such that: the processors 1212 include two, three, four, five, or more multi-core processors; the network interface devices 1216 include a first network interface device that implements Ethernet and a second network interface device that implements WiFi and/or Bluetooth; and the memory devices 1214 include a RAM and a flash memory or hard disk.

As previously noted, whenever it is described in this document that a software module or software process performs any action, the action is in actuality performed by underlying hardware elements according to the instructions that comprise the software module. In such embodiments, the following applies for each software module: (a) the elements of the client device 1210 (i.e., the one or more processors 1212, one or more memory devices 1214, one or more network interface devices 1216, one or more display interfaces 1218, and one or more user input adapters 1220), or appropriate combinations or subsets of the foregoing, are configured to, adapted to, and/or programmed to implement each or any combination of the actions, activities, or features described herein as performed by the component and/or by any software modules described herein as included within the component; (b) alternatively or additionally, to the extent it is described herein that one or more software modules exist within the component, in some embodiments, such software modules (as well as any data described herein as handled and/or used by the software modules) are stored in the respective memory devices (e.g., in various embodiments, in a volatile memory device such as a RAM or an instruction register and/or in a non-volatile memory device such as a flash memory or hard disk) and all actions described herein as performed by the software modules are performed by the respective processors in conjunction with, as appropriate, the other elements in and/or connected to the client device 1210; (c) alternatively or additionally, to the extent it is described herein that the component processes and/or otherwise handles data, in some embodiments, such data is stored in the respective memory devices (e.g., in some embodiments, in a volatile memory device such as a RAM and/or in a non-volatile memory device such as a flash memory or hard disk) and/or is processed/handled by the respective processors in conjunction, as appropriate, the other elements in and/or connected to the client device 1210; (d) alternatively or additionally, in some embodiments, the respective memory devices store instructions that, when executed by the respective processors, cause the processors to perform, in conjunction with, as appropriate, the other elements in and/or connected to the client device 1210, each or any combination of actions described herein as performed by the component and/or by any software modules described herein as included within the component.

The hardware configurations shown in the figure and described above are provided as examples, and the subject matter described herein may be utilized in conjunction with a variety of different hardware architectures and elements. For example: in many of the Figures in this document, individual functional/action blocks are shown; in various embodiments, the functions of those blocks may be implemented using (a) individual hardware circuits, (b) using an application specific integrated circuit (ASIC) specifically configured to perform the described functions/actions, (c) using one or more digital signal processors (DSPs) specifically configured to perform the described functions/actions, (d) using the hardware configuration described above, (e) via other hardware arrangements, architectures, and configurations, and/or via combinations of the technology described in (a) through (e).

### Technical Advantages of Described Subject Matter

The technology described herein includes a flight control system that can command more power from one electric motor (set of windings) or less from the other. This approach would allow the total power to be at the desired level, while also balancing the electrical loading on each battery system. The advantage of this approach is that it does not require any additional hardware to be added to the vehicle for the specific purpose of balancing battery state of charge across the isolated battery systems. That is, the technology described herein provides an improved load balancing approach across different electrical (e.g., battery) systems in a vehicle thus improving the overall operation of the vehicle as well as the associated electrical and/or control system.

### Further Applications of Described Subject Matter

As used in this document, the term “non-transitory computer-readable storage medium” includes a register, a cache memory, a ROM, a semiconductor memory device (such as a D-RAM, S-RAM, or other RAM), a magnetic medium such as a flash memory, a hard disk, a magneto-optical medium, an optical medium such as a CD-ROM, a DVD, or Blu-Ray Disc, or other type of device for non-transitory electronic data storage.

As used in this document, the term “and/or” includes any and all combinations of one or more of the associated listed items.

In the following description, for purposes of explanation and non-limitation, specific details are set forth, such as particular nodes, functional entities, techniques, protocols, etc. in order to provide an understanding of the described technology. It will be apparent to one skilled in the art that other embodiments may be practiced apart from the specific details described below. In other instances, detailed descriptions of well-known methods, devices, techniques, etc. are omitted so as not to obscure the description with unnecessary detail.

Whenever it is described in this document that a given item is present in “some embodiments,” “various embodiments,” “certain embodiments,” “certain example embodiments, “some example embodiments,” “an exemplary embodiment,” or whenever any other similar language is used, it should be understood that the given item is present in at least one embodiment, though is not necessarily present in all embodiments. Consistent with the foregoing, whenever it is described in this document that an action “may,” “can,” or “could” be performed, that a feature, element, or component “may,” “can,” or “could” be included in or is applicable to a given context, that a given item “may,” “can,” or “could” possess a given attribute, or whenever any similar phrase involving the term “may,” “can,” or “could” is used, it should be understood that the given action, feature, element, component, attribute, etc. is present in at least one embodiment, though is not necessarily present in all embodiments. Terms and phrases used in this document, and variations thereof, unless otherwise expressly stated, should be construed as open-ended rather than limiting. As examples of the foregoing: “and/or” includes any and all combinations of one or more of the associated listed items (e.g., a and/or b means a, b, or a and b); the singular forms “a”, “an” and “the” should be read as meaning “at least one,” “one or more,” or the like; the term “example” is used provide examples of the subject under discussion, not an exhaustive or limiting list thereof; the terms “comprise” and “include” (and other conjugations and other variations thereof) specify the presence of the associated listed items but do not preclude the presence or addition of one or more other items; and if an item is described as “optional,” such description should not be understood to indicate that other items are also not optional.

Although process steps, algorithms or the like, including without limitation with reference to any of the figures, may be described or claimed in a particular sequential order, such processes may be configured to work in different orders. In other words, any sequence or order of steps that may be explicitly described or claimed in this document does not necessarily indicate a requirement that the steps be performed in that order; rather, the steps of processes described herein may be performed in any order possible. Further, some steps may be performed simultaneously (or in parallel) despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary, and does not imply that the illustrated process is preferred.

Although various embodiments have been shown and described in detail, the claims are not limited to any particular embodiment or example. None of the above description should be read as implying that any particular element, step, range, or function is essential. All structural and functional equivalents to the elements of the above-described embodiments that are known to those of ordinary skill in the art are expressly incorporated herein by reference and are intended to be encompassed

While the technology has been described in connection with what is presently considered to be an illustrative practical and preferred embodiment, it is to be understood that the technology is not to be limited to the disclosed embodiment, but on the contrary, is intended to cover various modifications and equivalent arrangements.

1. A system for energy management in a vehicle, the system comprising:
a processor; and
a memory configured to store computer readable instructions that, when executed by the processor, cause the system to:
determine an energy level of each battery from a plurality of batteries, wherein the energy level is associated with a charge state of each battery;
determine whether the energy level, associated with the charge state of each battery, satisfies a first criteria;
load-balance an electrical load of the plurality of batteries based on battery state information associated with the energy level of each battery from the plurality of batteries; and
adjust power levels of one or more motors associated with the plurality of batteries in association with load-balancing the electrical load of the plurality of batteries.

2. The system of claim 1, wherein determining whether the energy level satisfies the first criteria includes determining whether the energy level associated with the charge state of each battery is out of balance by more than a specified limit.

3. The system of claim 1, wherein load-balancing the electrical load of the plurality of batteries comprises:
obtaining the battery state information, associated with the plurality of batteries, from a battery management system; and
load-balancing the electrical load of the plurality of batteries based on the battery state information obtained from the battery management system.

4. The system of claim 1, wherein load-balancing the electrical load of the plurality of batteries comprises:
estimating the battery state information, associated with the plurality of batteries, based on a torque per motor value; and
load-balancing the electrical load of the plurality of batteries based on the estimated battery state information.

5. The system of claim 1, wherein balancing the power level of the one or more motors comprises:
determining, based on a mapping of the one or more motors to the plurality of batteries, an increase and/or decrease of the power level of the one or more motors;
increasing the power level of a first motor, of the one or more motors, based on the mapping; and
decreasing the power level of a second motor, of the one or more motors, based on the mapping.

6. The system of claim 5, wherein the system is further caused to:
pass the battery state information through a proportional-integral derivative (PID) controller; and
adjust torque commands for each motor of the one or more motors.

7. The system of claim 5, wherein the system is further caused to:
apply a fixed proportional power delta to each motor, of the one or more motors, based on the mapping of the one or more motors to the plurality of batteries.

8. The system of claim 1, further comprising a plurality of power distribution units operatively coupled to the plurality of batteries.

9. The system of claim 1, further comprising a plurality of rotors operatively coupled to the one or more motors.

10. An aircraft, comprising:
a plurality of batteries;
a plurality of motors; and
a power management system configured to:
determine an energy level of each battery from a plurality of batteries, wherein the energy level is associated with a charge state of each battery;
determine whether the energy level, associated with the charge state of each battery, satisfies a first criteria;
load-balance an electrical load of the plurality of batteries based on battery state information associated with the energy level of each battery from the plurality of batteries; and
adjust power levels of one or more motors associated with the plurality of batteries in association with load-balancing the electrical load of the plurality of batteries.

11. The aircraft of claim 10, wherein load-balancing the electrical load of the plurality of batteries comprises:
obtaining the battery state information, associated with the plurality of batteries, from a battery management system; and
load-balancing the electrical load of the plurality of batteries based on the battery state information obtained from the battery management system.

12. The aircraft of claim 10, wherein load-balancing the electrical load of the plurality of batteries comprises:
estimating the battery state information, associated with the plurality of batteries, based on a torque per motor value; and
load-balancing the electrical load of the plurality of batteries based on the estimated battery state information.

13. The aircraft of claim 10, wherein the power management system is further configured to:
pass the battery state information through a proportional-integral derivative (PID) controller; and
adjust torque commands for each motor of the plurality of motors.

14. The aircraft of claim 10, wherein the power management system is further configured to:
apply a fixed proportional power delta to each motor, of the plurality of motors, based on a mapping of the plurality of motors to the plurality of batteries.

15. A method for performing load management, the method comprising:
determining an energy level of each battery from a plurality of batteries, wherein the energy level is associated with a charge state of each battery;
determining whether the energy level, associated with the charge state of each battery, satisfies a first criteria;
load-balancing an electrical load of the plurality of batteries based on battery state information associated with the energy level of each battery from the plurality of batteries; and
adjusting power levels of one or more motors associated with the plurality of batteries in association with load-balancing the electrical load of the plurality of batteries.

16. The method of claim 15, wherein load-balancing the electrical load of the plurality of batteries comprises:
obtaining the battery state information, associated with the plurality of batteries, from a battery management system; and
load-balancing the electrical load of the plurality of batteries based on the battery state information obtained from the battery management system.

17. The method of claim 15, wherein load-balancing the electrical load of the plurality of batteries comprises:
estimating the battery state information, associated with the plurality of batteries, based on a torque per motor value; and
load-balancing the electrical load of the plurality of batteries based on the estimated battery state information.

18. The method of claim 15, wherein balancing the power level of the one or more motors comprises:
determining, based on a mapping of the one or more motors to the plurality of batteries, an increase and/or decrease of the power level of the one or more motors;
increasing the power level of a first motor, of the one or more motors, based on the mapping; and
decreasing the power level of a second motor, of the one or more motors, based on the mapping.

19. The method of claim 18, further comprising:
passing the battery state information through a proportional-integral derivative (PID) controller; and
adjusting torque commands for each motor of the one or more motors.

20. The method of claim 18, further comprising:
applying a fixed proportional power delta to each motor, of the one or more motors, based on the mapping of the one or more motors to the plurality of batteries.
